(19) United States
(12) Patent Application Publication
(10) Pub. No.: US 2023/0370975 A1
(43) Pub. Date: Nov. 16, 2023

(54) FUNCTIONAL TEXTILE AND METHODS OF MAKING AND USING SAME

(71) Applicant: FUNCTIONAL TEXTILE AND METHODS OF MAKING AND USING SAME

(72) Inventors: Stefan MUELLER, Wiehl (DE); WEIS Joachim, Rauschenberg (DE)

(21) Appl. No.: 18/026,197

(22) PCT Filed: Oct. 26, 2021
(86) PCT No.: PCT/EP2020/079637

§ 371 Date: Mar. 14, 2023

(51) Int. Cl. H04W 52/14; H04W 52/36; H04B 1/04

(52) U.S. Cl. CPC H04W 52/146; H04B 1/0475; H04W 52/367

(57) ABSTRACT

An apparatus includes at least one processor; and at least one memory including computer program code; the at least one memory and the computer program code configured to, with the at least one processor, cause the apparatus at least to: control receiving, by a user device from a network node, an uplink grant for an uplink transmission, and information indicative of at least one of an In-Band Emission requirement or an Error Vector Magnitude requirement for the uplink transmission; determine, by the user device, a maximum power reduction value for the uplink transmission based at least on the information indicative of at least one of an In-Band Emission requirement or an Error Vector Magnitude requirement; and control transmitting, by the user device for the uplink transmission, a signal at an output power based at least on the maximum power reduction value.

The invention relates to a functional textile comprising a textile substrate and a plurality of metallic functional conductors provided with insulation and at least one metallic first feed conductor provided with insulation, the functional conductors being connected to the feed conductor at contact points spaced from one another along the first feed conductor.

The present invention relates to a functional textile with conductive properties advantageously usably for heating purposes. For example, it is known to heat seats, backrests or interior trim parts with such functional textiles in motor vehicles.

Within the scope of the invention, the functional textile comprises a textile substrate usually formed from filaments, in particular from plastic filaments, and metallic functional conductors provided with insulation are also provided in or on the textile substrate.

In the context of the invention, basically different textiles with a uniform structure come into consideration. Corresponding textiles with a uniform or substantially uniform structure can be made for example, by weft knitting, warp knitting, or weaving. In principle, however, the textile substrate can also be formed by a fleece (nonwoven) in which individual filaments or fibers are randomly arranged, deposited and aligned to a certain extent.

According to the invention, the textile substrate can in particular also be a spacer textile. According to their general construction, spacer textiles each comprise a first flat or planar textile layer, a second flat or planar textile layer spaced therefrom and usually parallel thereto, and spacer filaments connecting the textile layers to each other.

Spacer fabrics can be used to form heating textiles. Spacer fabrics are characterized by a low basis weight, a comparatively open and air-permeable structure and elastic properties in the thickness direction. In the case of spacer textiles having a first flat knitted layer, a second flat knitted layer, and spacer filaments connecting the knitted layers, the heating conductors are then worked into the structure of one of the knitted layers that is usually formed from plastic filaments.

DE 10 2006 038 612 A1 discloses a functional textile in the form of a knitted spacer section in which uninsulated heating conductors are incorporated into a flat knitted layer and touch one another. Such a configuration forms a planar, conductive structure that can be contacted by two lateral, knitted feed conductors. ?Since all the conductor filaments form a common electrically conductive structure with a plurality of contact points, a punctiform contacting is generally sufficient. However, in practice it may also sometimes result in locally uneven or inadequate heating.

DE 10 2018 111 893 [US 2021/0315060] describes a heating textile for transferring heat where electrically conductive fiber strands are present, and where contacting of the fiber filaments is also provided by physical contact with stitch-like connections.

With regard to long-term function, however, many known heating textiles with uninsulated heating conductors are in need of improvement. In this context, it is also customary for functional textiles and in particular heating textiles for use in motor vehicles to be subjected to extremely demanding tests in advance and, inter alia, mechanical loads are exerted and the functional textiles are also brought into contact with foreign substances such as conductive and/or oxidizing liquids. In the case of uninsulated heating conductors, failure can result, for example, by corrosion and oxidation.

In order to avoid the described disadvantages in the case of uninsulated systems that are easy to contact, different approaches have been pursued. Even when corrosion-resistant nickel-copper alloys are used for the heating conductors, only limited stability results.

According to DE 10 2015 114 778, it is proposed in this context to provide filaments with a conductive coating, in particular of silver, as a result of which corrosion is at least reduced. However, the costs associated with manufacture of such a knitted spacer fabric are comparatively high. This applies in particular if the available conductive cross section is based on the comparatively thin coating. Resistance is also in need of improvement. It should be noted here that a thin coating of metal and in particular silver in comparison to a highly stretchable plastic filament as a core, so that cracks or microcracks can arise in the metallic coating when the entire filament is stretched during production or use. In the case of a polyamide preferred in combination with silver as the material for the filaments, there is then also the problem of swelling on exposure to moisture, as a result of which further damage results.

A functional textile of the generic type in the form of a spacer knitted fabric section is known from DE 10 2009 013 250, where insulated systems of the generic type and alternatively uninsulated systems are described with regard to the heating conductors as functional conductors and feed conductors. In the case of bare functional conductors and a bare feed conductor, secure contacting can be achieved with an electrically conductive adhesive. Furthermore, welding can also take place using a correspondingly high current flow and the resistance at the contact points resulting in melting, so that an integral metal/metal bond can be formed.

DE 10 2018 111 893 [US 2021/0315060] discloses a textile substrate for forming a heating element, contacting also taking place with use of adhesive, namely a hot-melt adhesive. Stitch filaments are additionally provided for fixing heating conductors to contact conductor filaments.

If, on the other hand, according to the generic configuration, the functional conductors and the at least first feed conductor are provided with insulation, the insulation can be melted to such an extent that the functional conductors and the first feed conductor are connected in an electrically conductive manner in a touching contact. Particularly with regard to long-term loads or the aforementioned material tests, however, such embodiments of the functional textile are also in need of improvement.

Functional textiles of the generic type in the form of spacer knitted fabrics are also known from DE 10 2019 103 934 [US 2020/0263334] and DE 10 2019 103 935 A1. In the described heating inserts in the form of a spacer warp-knitted fabric section, a plurality of heating conductors extending substantially along a first direction extend approximately parallel to one another, and their ends are connected. The specific type of contacting is not specified here.

A fabric with conductive function conductors is known from EP 1 137 322 B1. The conductors that are preferably formed from carbon fibers are provided with an insulating coating. By melting this coating layer, the feed conductors of carbon fiber can be brought into electrical contact.

In order to avoid the problem of complex contacting, according to DE 10 2009 010 415 A1 a single electrically conductive resistance wire is laid in a meander into a textile substrate in the form of a knitted spacer fabric. Manufacture is extremely complicated. The arrangement between the knitted layers results in a certain insulation in both directions.

On the other hand, when the functional filaments are integrated into one of the knitted layers, it is particularly advantageous for heating to take place mainly in the corresponding knitted layer, so that a certain level of thermal insulation is already achieved by the spacing effected by the spacer filaments and the air layer thereby provided between the knitted layers. When heating interior spaces, for example in motor vehicles, the knitted layer provided with the functional conductors is then advantageously turned inward toward the interior so that the heat losses outward of the body or the outer skin of such a motor vehicle are also minimized.

DE 4 239 068 discloses a spacer fabric having a plurality of heating conductors and two feed conductors spaced from one another. The heating conductors and the feed conductors can have insulation that is interrupted at the intersection points. The exact nature of the connection is not described.

The object of the present invention is to provide a functional textile of the generic type, in particular for heating purposes that has good functional properties and is particularly robust and resistant to wear. Further objects are a method of making the functional textile and a preferred use of the functional textile.

The object of the invention and attainment of the object are a functional textile according to claim 1, a method of forming a functional textile according to claim 13, and the use of a functional textile according to claim 19.

Starting from a functional textile of the generic type, according to the invention it is first provided according to the invention that the insulation of the functional conductors and the insulation of the first feed conductor are at least partially displaced and/or removed at the contact points, and that then the functional conductors and the first feed conductor are thus then connected to the contact points by an integral metal/metal bond.

With the integral metal/metal bond, the metallic structure of the functional conductor merges into the metallic structure of the first feed conductor at each contact point which different form a mere physical touching or engagement. The functional conductors and the first feed conductor are thus connected directly to one another at least partially by soldering or welding, so that the integral metal/metal bond alone has a certain strength of its own.

The integral metal/metal bond ensures a low electrical resistance of the contact points. The integral metal/metal bond remains unchanged at least up to a certain load limit unchanged by mechanical effects and can also absorb tensile forces to a certain extent. Relative movements that can lead to contact resistances, electrically induced corrosion or other damage, are thus reliably avoided. The integral metal/metal bond is also largely protected from external influences.

In order to make the integral metal/metal bond described in particular by pressure and temperature, the insulation of the functional conductors and the insulation of the first feed conductor are at least partially displaced and/or removed at the contact points. A preferred method whereby such a functional textile can be made in an advantageous manner is described below.

According to a preferred development of the invention, insulation material is applied separately to the contact points. This separately applied insulation material fills where the insulation of the functional conductors and the insulation of the first feed conductor has been removed at the contact points. The separately applied insulation material ensures electrical insulation at the contact points so that overall a completely insulated system is produced. Electrochemical corrosion or other impairment from foreign substances is thus largely ruled out. This also has the advantage that an effective protective layer is provided with the insulations of the functional conductors and of the first feed conductor on the one hand and the separately applied insulation material on the other hand.

In addition, the insulation material applied separately at the contact points also brings about a mechanical reinforcement with certain mechanically compensating properties. At the contact points, the combination on the one hand of the metallic bond and the separately applied insulation material on the other hand imparts a particularly high strength, which significantly exceeds the sum of the strength of the metal/metal bond alone or only the strength of a separately applied insulation material.

As also explained below, the insulation of the function conductors, the insulation of the first feed conductor, and the separately applied insulation material are usually formed by a plastic, different types of plastic being suitable. The separately applied insulation material usually differs materially from the insulation of the functional conductors and the insulation of the first feed conductor. Accordingly, the different materials on the functional textile itself can be easily analyzed and optionally differentiated.

The functional conductors are provided in particular for heating purposes, but the present invention is not limited thereto. In addition or as an alternative, functional conductors may also be provided, for example, in connection with sensors, occupancy detection or the like.

In the various applications, it is usually provided that the functional conductors have a significantly smaller cross-sectional area than the first feed conductor and correspondingly have significantly greater resistance. Accordingly, the functional conductors can preferably be formed by a comparatively thin wire insulated, for example, with a lacquer layer. Correspondingly coated wires are available with different metallic materials, in different thicknesses and with different coatings.

As will also be described further below, insulation based on polymer and in particular in the form of insulation lacquer also provides advantages in manufacture of the functional textile if the functional conductors are integrated into the textile substrate. If the functional conductors are made for example, in a weaving, weft knitting, or warp-knitting process on corresponding textile machines, there is lower friction and lower wear in comparison with a bare, uninsulated metal wire by the plastic-base insulating lacquer.

The insulating lacquer can be formed, for example, based on polyurethane, and such lacquers frequently are thermosetting.

As already described above, the first feed conductor advantageously has a larger line cross-sectional area. In this connection, according to a preferred embodiment of the invention, the first feed conductor is formed by conductive metallic strands, in particular copper strands. The copper strands are formed substantially from copper or a copper alloy. The first feed conductor can, in particular in the case of a configuration made of a stranded metallic conductor, have a coating of thermoplastic material as insulation that is extruded onto the metallic conductor strands. Using extruded thermoplastic material has the advantage that the metallic conductor strand is sheathed. However, the spaces between individual strands of the conductor are not or only partially filled. In principle, however, the insulation of the first feed conductor can also be formed by a different type of coating, for example by immersion in liquid thermoplastic plastic or a curing thermosetting plastic.

With regard to the processing and handling of the first feed conductor and the resistance capability, a thermoplastic elastomer (TPE) is preferably provided as the thermoplastic material forming an insulating layer on the first feed conductor. In principle, all types of thermoplastic elastomers are suitable, and thermoplastic elastomer based on polyester or copolyester (TPE-E) is preferred.

As also described below in connection with the method of forming the functional textile, the material forming the insulation is usually applied in liquid form at the contact points. In addition to a molten application of thermoplastic material, the separate insulation material can also be applied at room temperature, depending on composition, and then cured. Advantageously, the curing or setting is then carried out by activation, in particular by UV light. In this context, it is also possible to cure an initially liquid-applied insulation material within a few seconds, for example in about 4 seconds, by irradiation with UV light. In a particularly advantageous manner, the functional textile can then be immediately thereafter further processed or stored. This also has the advantage that high strength is imparted at the contact points by the integral metal/metal bond on the one hand and the applied insulation material on the other.

If, according to the preferred variant described above, the liquid-applied insulation material cures by activation, two chemical components can also be combined for this purpose (2-K insulation materials and adhesives), and a correspondingly accelerated curing can also be achieved on first contact with air and/or moisture.

According to a preferred embodiment of the invention, the functional conductors can be connected to the first feed conductor in a parallel circuit. Furthermore, for example, two interconnected functional conductors can be connected in series as a group, and in turn a plurality of groups formed in this way can be connected in parallel to one another. In principle, other electrical connections are also possible.

The functional conductors can extend substantially along a first direction, and the first feed conductor extends at an angle thereto along a second direction. Nonetheless, the functional conductors do not have to all extend parallel along the first direction and neither have to extend parallel to one another. As is basically known, the individual feed conductors can also extend in a wave form or a zigzag. In addition, adjacent functional conductors can also have a bigger or smaller spacing from one another at least in regions with a nonparallel profile. By appropriate measures, for certain applications, for example, contours of the functional textile that deviate from a rectangular shape can be produced and/or individual regions with functional conductors can be cut out.

It is preferably provided that the individual function conductors do not intersect, even if this is intrinsically safe due to the insulation.

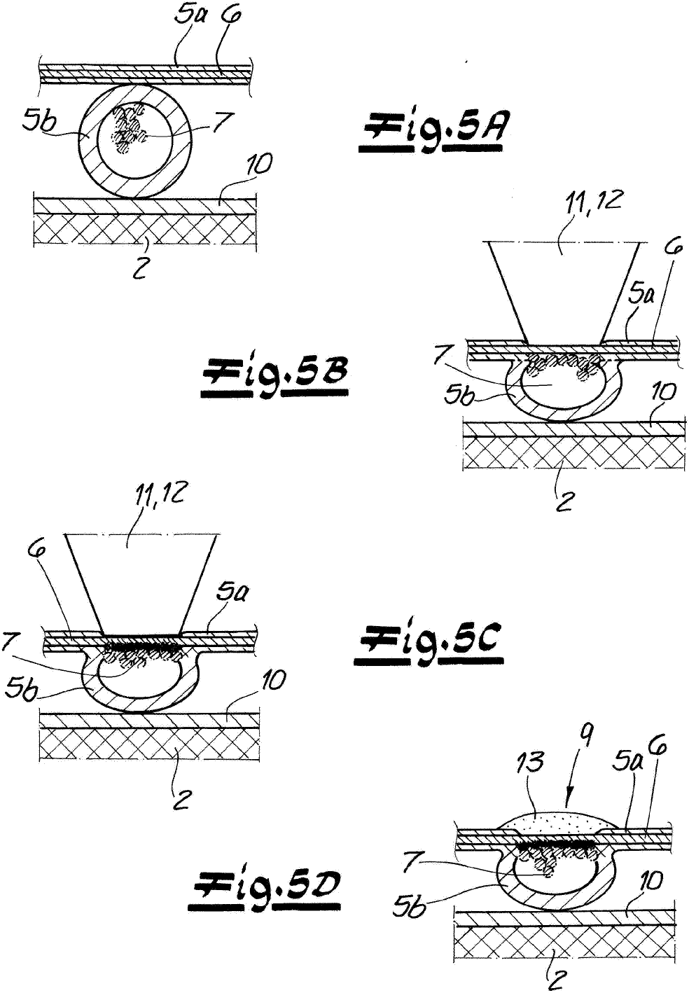

With regard to a possible arrangement of the functional conductors, reference is made to above-cited DE 10 2019 103 934 [US 2020/0263334] that relates to a section with function conductors in the form of heating conductors. Variation possibilities with regard to the arrangement of heating conductors are shown, for example, in FIG. 4A to 4E and FIGS. 5.

In order to contact the functional conductors usually adjacent an edge of the functional textile with the first feed conductor, the latter extends at an angle to the individual functional conductors, so that contact points are formed at the crossing points. In this case, the second direction can extend at or substantially at a right angle to the first direction. In principle, depending on the material cross-sectional shape or use, it may also be expedient if the first feed conductor extends obliquely from a right angle. The first direction and the second direction can then, for example, enclose an acute angle between 60° and 90°.

In principle, it is also possible that the first feed conductor does not extend straight and extends, for example, along an arc. With the right shape, an adaptation can take place for various applications, even if however increased production effort cannot be ruled out.

According to a preferred development of the invention, the functional conductors are connected between the first feed conductor and a second feed conductor, and the second feed conductor extends in the first direction at a spacing from the first feed conductor. In the context of such an embodiment, the two feed conductors then form a feed and ground line for the functional conductors. When used in a direct current system, in particular of a motor vehicle, one of the two feed conductors can then advantageously be assigned to ground the entire electrical system.

If, according to a preferred embodiment, a second feed conductor is provided, all the features and variation possibilities described in connection with the first feed conductor also apply to the second feed conductor.

As already explained above, different types of textile substrate can be provided within the scope of the invention. The textile substrate can be formed, for example by a weaving, weft-knitting, or warp-knitting process, and alternatively nonwovens with a certain statistical density of filaments and fibers come into consideration. The textile substrates can be formed as a web by knitting or knitting process both as a simple textile layer or preferably as a spacer textile with a first flat textile layer, a second flat textile layer, and spacer filaments connecting the two textile layers.

Irrespective of the specific embodiment of the basic textile, it is advantageous with regard to the formation of the functional textile if the individual functional conductors are on an outer face of the textile substrate in the region of the contact points or rest on the textile substrate. The first feed conductor can then be inserted there between the textile substrate and the functional conductors, thereby forming the contact points on the corresponding outer face of the textile substrate. Alternatively, it is also possible for the textile substrate to be cut to size before manufacture of the contact points in such a way that the textile substrate is removed in the region of the contact points to be formed. However, it is also preferred if the functional conductors extend out of the associated surface and are thus exposed in an empty area.

According to a particularly preferred embodiment of the invention, the textile substrate is formed by a knitted spacer fabric with a first flat knitted layer, a second flat knitted layer and spacer filaments connecting the knitted layers, the functional conductors being part of the first knitted layer.

If the textile substrate is formed by a nonwoven or a woven fabric, the functional conductors can be introduced into the textile substrate straight or, if appropriate, also in a zigzag.

In the case of a weft knitted or warp knitted fabric, the functional conductors can in principle also form stitches like the filaments of the textile substrate that are usually made of plastic. However, it is preferably provided that the functional conductors are incorporated into the textile substrate without stitch formation. In this context, for example, a zigzag configuration is expedient, as is known in principle from the documents DE 10 2009 013 250 B3, DE 4 239 068 C2, DE 10 2019 103 934 [US 2020/0263334] and DE 10 2019 103 935.

The functional conductors can have, for example, a diameter of between 25 µm and 200 µm, particularly preferably between 40 µm and 100 µm. In particular for use for heating purposes, the electrical resistance of the functional conductors can be between 1 Ω (ohm)/m and 280 Ω/m (ohms per meter), preferably between 5 Ω/m and 70 Ω/m.

The diameter specified above relates to the usual circular cross-sectional shape of the wire. In principle, it is also possible to use metal wires whose cross-section is not circular. The cross-sectional area then advantageously corresponds to the area of a circular wire with the diameter indicated above.

The first feed conductor and, if provided, the second feed conductor have a larger cross-section and can each be formed particularly preferably from multiple metallic conductor strands, in particular copper filaments. The copper filaments are formed substantially from copper or a copper alloy.

With regard to good conductivity and good processability, the functional conductors and/or the first feed conductor or the optionally provided second feed conductor can be formed from copper wire or copper conductors that in turn consists of a plurality of copper filaments. In the case of copper or a copper alloy as material for the functional conductors and/or the feed conductors, an additional metallic coating may also be expedient. For example, copper wire can be tin-plated, in particular hot-plated. This results in the advantage that the underlying copper or the underlying copper alloy is better protected by the coating of tin with a typical thickness of about 1 µm to 2 µm and the integral metal/metal contact provided according to the invention can also be formed more easily. Irrespective of manufacture from substantially pure copper or a copper alloy, the corresponding wires or filaments are referred to in the context of the invention as copper wires or copper wires.

In order to produce the integral metal/metal bond, the usually distinctly different cross sections of the functional conductors on the one hand and of the first feed conductor or optionally provided second feed conductor and the different heat conduction resulting therefrom are also to be taken into account. Thus, it is first expedient if the first feed conductor and optionally the second feed conductor are positioned between the functional conductors pulled out of the textile substrate and the textile substrate. When viewed from outside, the functional conductors then lie on top of the first feed conductor or the second feed conductor, so that a suitable connection can be formed more easily there.

Precisely due to the different size and heat conduction, the formation of the contact points can be difficult. Experiments have shown that manufacture of a reliable connection by ultrasonic welding or laser welding is at least not readily possible.

Against this background, the invention also relates to a method of forming a functional textile that in particular has the features described above. Of course, the method described below can also have the features described above.

According to the method of forming the functional textile, a textile substrate having a plurality of metallic functional conductors incorporated therein is provided, with at least one metallic feed conductor provided with insulation being positioned such that it crosses the functional conductors at crossing points where the insulation of the functional conductor and the insulation of the functional conductor are at least partially displaced and/or removed for forming contact points by only the local action of pressure and temperature, and the functional conductor, and the feed conductor are left connected by an integral metal/metal bond and separate insulation material is then applied to the contact points thus formed.

The contact points are preferably formed in succession with a thermal welding tool that can also be referred to as a thermode. Corresponding welding tools are known from the field of electronics.

The orientation of the individual crossing points for forming the contact points can be controlled manually, computer-supported or fully automatically. In a manual procedure, optical aids such as microscopes, magnifying glasses or cameras can be used. Cameras can also be used for a computer-assisted or fully automatic process control with corresponding electronic control.

According to a particularly preferred embodiment of the invention, when the thermal welding tool is used, it is provided that the welding tool is heated in pulses for making the contact points, the insulation of the associated functional conductor and of the feed conductor being at least partially burnt or melted off and thereby removed by a first heat pulse, and the function conductors and the feed conductor are then integrally connected by a second heat pulse, in particular soldered or welded together. With such a two-part method, the steps that differ with respect to their requirements can be optimized separately.

The welding tool advantageously has a tip that is optimized with regard to its size to the formation of the contact points. The effective area of the tip is advantageously so large that the welding tool can be positioned at each of the crossing points without excessive effort and can heat the functional conductor and the feed conductor that is usually located underneath it to a sufficient extent. On the other hand, with regard to process speed, energy efficiency and material saving, the effective area should not be too large. The effective area at the tip of the welding tool can be, for example, between 0.1 mm² and 8 mm², in particular between 0.3 mm² and 3 mm².

As already explained above, the separately provided insulation material is preferably applied in liquid form at the contact points formed and is cured by activation.

With regard to the formation of the contact points by local action of pressure and temperature, a suitable base or counter surface must be provided precisely in the case of spacer textiles, in particular if the action of pressure and temperature takes place by the thermal welding tool described above. In addition, the textile substrate should also be protected from excessive heat.

Against this background, according to a preferred development of the method, the functional conductors are on an outside face of the textile substrate, in particular in the form of a knitted spacer fabric, at the contact points, and the first feed conductor is fitted between the functional conductors and the textile substrate, namely a protective strip is temporarily interposed between the functional conductor and the textile substrate for making the contact points. The protective strip can be formed, for example, from a temperature-resistant plastic that is removed again after the bonding at the contact points.

Alternatively, however, it is also possible for the textile substrate to be trimmed before bonding the contact points in such a way that the functional conductors are exposed in the corresponding region.

Finally, the invention also relates to the use of the previously described functional textile for heating, in particular interior spaces of a motor vehicle. This use preferably takes place in that the functional textile has between 8 and 40, in particular between 12 and 26 functional conductors as heating conductors that, for example as explained above, can be connected individually or in pairs in groups in an electrical parallel circuit. The number of 8 to 40 heating conductors is useful for many applications such as door trim, seating or instrument panels, but the invention is not limited to the specified number. For certain applications such as, for example, heated steering wheels or large-area headliners, fewer or more heating conductors can also be provided.

In this case, it is particularly preferably provided that a decorative layer is provided on the textile substrate, and the functional conductors are on a face of the textile substrate turned toward the decorative layer. The decorative layer can be, for example, leather, artificial leather, a film or a covering material.

If the textile substrate according to a preferred embodiment of the invention is formed by a spacer fabric having a first flat knitted layer, a second flat knitted layer, and spacer filaments therebetween, the functional conductors can then be provided, for example, in the first knitted layer, and the decorative layer then is fitted atop the first knitted layer. The decorative layer facing the interior of a motor vehicle, for example, can then be heated very quickly along with the feed conductors lying directly underneath, by a sufficient current flow, while good thermal insulating is achieved in the opposite direction by the spacing by means of the spacer filaments and the air layer thus provided between the knitted layers.

If, for example, a door inner lining is equipped with the functional textile for heating purposes, a very rapid heat output occurs to the interior of the motor vehicle, while the heat losses can be limited to the outside, for example through a vehicle door.

Alternatively, the functional textile can also be used in other areas of a motor vehicle, for example in seat surfaces, armrests, instrument panels, steering wheels or the like.

It should also be taken into account that the waste heat of an internal combustion engine is not available for use in increasing electrified vehicles. Against this background, it is also advantageous for occupants of a motor vehicle to provide a pleasant heat sensation by contact heat or radiant heat, without the entire interior space having to be heated excessively.

The invention is described by way of example below with reference to a drawing in which:

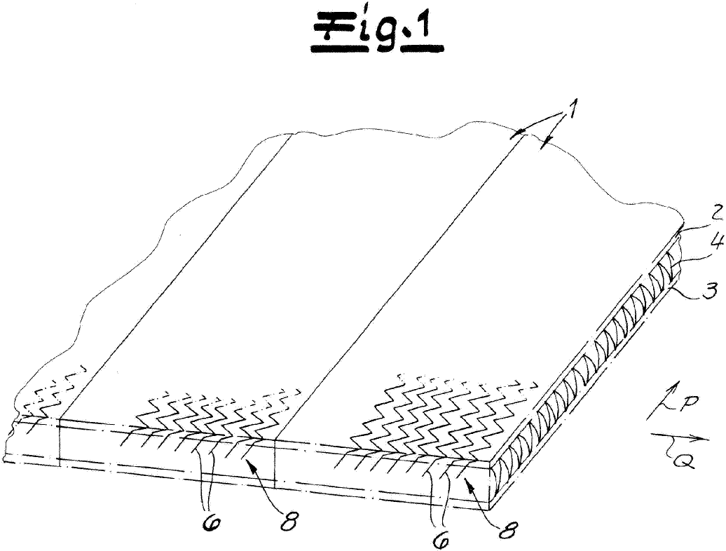

FIG. 1 is a perspective view of a knitted spacer fabric for making a functional textile according to the invention,

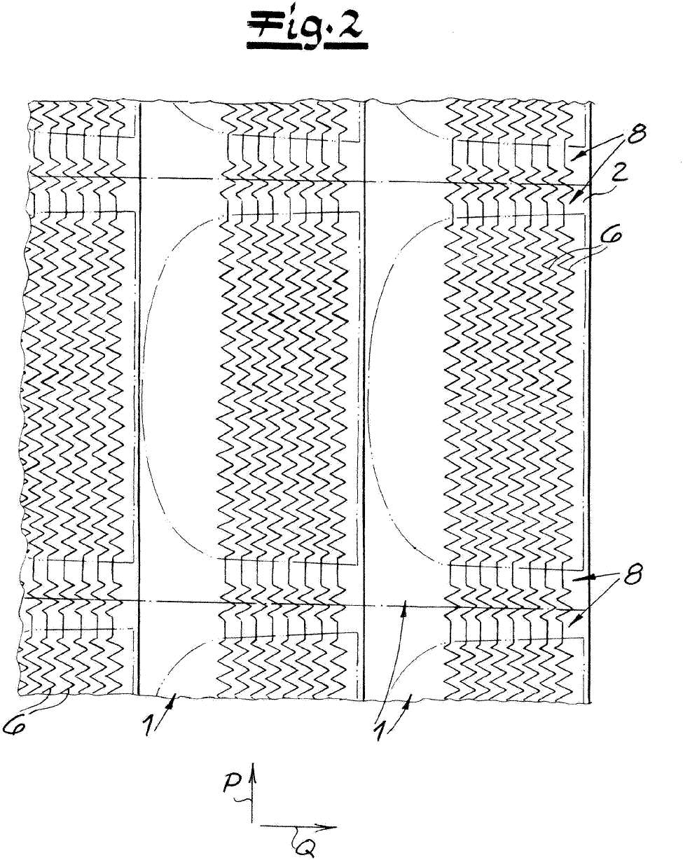

FIG. 2 is a plan view of the spacer fabric according to FIG. 1,

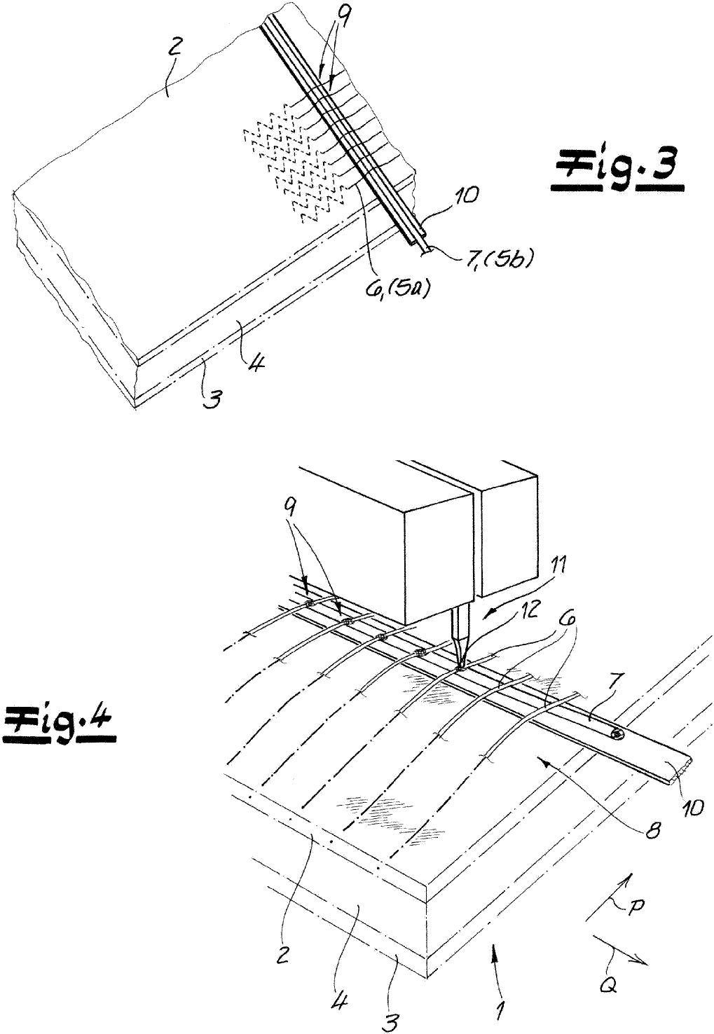

FIG. 3 shows the spacer fabric of FIGS. 1 and 2 with an additional feed conductor,

FIG. 4 shows an apparatus for making the functional textile, and

FIGS. 5A to 5D show method steps for making the functional textile.

FIGS. 1 and 2 show a knitted spacer fabric from which individual sections 1 can be cut. Functional textiles according to the invention are then formed from the individual sections 1 as described in detail below.

As is customary, the sections 1 each have a first knitted layer 2 and a second knitted layer 3 that have wales extending in a production direction P and rows extending in a transverse direction Q. The knitted layers 2, 3 are connected by spacer filaments 4. The structure described corresponds to the usual design of a knitted spacer fabric. The spacer fabric is made of plastic filaments, in particular based on polyester, is formed from a functional conductor 6 provided with insulation 5a and also a feed conductor 7 with insulation 5b, in the sense of the present invention, the plastic filaments forming a textile substrate in the sense of the present invention. The functional conductors 6 provided with insulation 5a are heating conductors and extend substantially along the production direction P. The functional conductors 6 also extend in a zigzag in the first knitted layer 2 and themselves do not form stitches and are correspondingly only laid into the first knitted layer 2. Accordingly, the functional conductors 6 can be installed in a low-wear manner and at high position speeds.

With regard to the manufacture of the illustrated sections, the insulation 5a of the functional conductors 6 is advantageously formed, for example, by an insulating lacquer with a polyurethane base.

The installation of the functional conductors 6 in the first knitted layer 2 can be carried out according to DE 10 2019 103 934 [US 2020/0263334], reference being made to the described technical embodiments for this purpose.

In order to make good electrical connections with the functional conductors 6 as easily as possible, the functional conductors 6 are outwardly exposed on the outer face of the first knitted layer 2 at connection regions 8 and initially there just lay on the first knitted layer 2.

According to FIG. 3, the feed conductor 7 provided with the insulation 5b is then threaded between the exposed functional conductors 6 and the first knitted layer 2, forming a functional textile in particular for heating purposes usually with two such feed conductors 7. For simplicity of illustration, however, the measures provided in the context of the invention are described below only with a feed conductor 7, so the second feed conductor 7 of the functional textile is then contacted in the same way.

In order to form a base for making contact points 9 by pressure and temperature, a protective strip 10 is temporarily placed between the feed conductors 7 shown in FIG. 3 and the first knitted layer 2. After formation of the contact points 9, the protective strip 10, formed for example from a temperature-resistant plastic, is removed.

FIG. 4 shows an apparatus for forming the contact points 9, where the action of pressure and temperature are applied locally with a thermal welding tool 11, also referred to as a thermode, at points of intersection of the functional conductors 6 with the feed conductor 7 such that the insulation 5a of the functional conductor 6 and the insulation 5b of the feed conductor 7 are at least partially melted off and/or removed, and the functional conductor 6 and the feed conductor 7 are left connected by an integral metal/metal bond. As shown below in connection with FIGS. 5A to 5D, the action of pressure and temperature is preferably effected by the welding tool 11 with pulsed heating.

According to FIG. 4, the welding tool 11 has a tip 12 whose effective surface area can be between 0.1 mm² and 8 mm², in particular between 0.3 mm² and 3 mm².

FIG. 5A shows, in accordance with FIG. 3, in a sectional view one of the functional conductors 6 and the underlying feed conductor 7, and the protective strip 10 underneath the feed conductor 7. The first knitted layer 2 lies below the protective strip 10.

According to FIG. 5B, only the insulation 5a of the function conductor and the insulation 5b of the feed conductor 7 are displaced and/or removed with a first heat pulse, and the function conductor 6 and the feed conductor 7 then bear directly against one another.

According to FIG. 5C, with a second heat pulse, the function conductor 6 and the feed conductor 7 are bonded integrally to one another.

According to FIG. 5D, separate insulation 13 is applied separately as a liquid to the contact points 9 thus formed, and is preferably cured and cured by activation, in particular by UV light. Complete electrical insulation is then obtained and particularly good strength and load-bearing capacity are imparted to the cured insulation material 13 on the one hand and to the integral metal/metal bond between the feed conductor 7 and the functional conductors 6.

As shown in FIG. 4, the contact points 9 spaced from one another along the feed conductor 7 are successively formed in the described manner, the contact points 9 produceable both manually, computer-supported or also fully automatically.

What is claimed is:

1. In a functional textile comprising a textile substrate having a plurality of metallic functional conductors provided with insulation, and at least one metallic first feed conductor provided with insulation, the functional conductors being connected to the first feed conductor at contact points spaced from one another along the first feed conductor, the improvement wherein:
the insulation of the functional conductors and the insulation of the first feed conductor are at least partially displaced and/or removed at the contact points, and
the functional conductors and the first feed conductor are electrically bonded together at the contact points by a metal/metal bond.

2. The functional textile according to claim 1, further comprising insulation material applied separately at the contact points.

3. The functional textile according to claim 2, wherein the insulation material differs materially from the insulation of the functional conductors and of the insulation of the first feed conductor.

4. The functional textile according to claim 1, wherein the functional conductors extend substantially along a first direction, and the first feed conductor extends at an angle thereto along a second direction.

5. The functional textile according to claim 4, wherein the functional conductors are connected between the first feed conductor and a second feed conductor, and the second feed conductor is spaced in the first direction at a spacing from the first feed conductor.

6. The functional textile according to claim 1, wherein the textile substrate is a knitted spacer fabric having a first flat knitted layer, a second flat knitted layer, and spacer filaments connecting the knitted layers, the functional conductors being in sections in the first knitted layer.

7. The functional textile according to claim 6, wherein the functional conductors are incorporated into the textile substrate without stitch formation.

8. The functional textile according to claim 1, wherein the insulation of the functional conductors is formed by an insulating lacquer.

9. The functional textile according to claim 1, wherein the first feed conductor is formed by a metallic conductor strand that has a jacket of thermoplastic material as insulation.

10. The functional textile according to claim 1, wherein the first feed conductor is on the textile substrate and the functional conductors extend out of the textile substrate in the region of the first feed conductor.

11. The functional textile according to claim 1, wherein the functional conductors and/or the first feed conductor are/is essentially formed from copper or a copper alloy.

12. A method of making the functional textile according to claim 1, the method comprising the steps of:
a) providing the textile substrate with a plurality of metallic functional conductors incorporated therein and provided with insulation,
b) providing at least one metallic feed conductor with insulation in such a way that it crosses the functional conductors at crossing points
c) partially displacing and/or removing the insulation of the respective feed conductor and the insulation of the feed conductor at the crossing points for forming contact points by only local action of pressure and temperature, and the respective feed conductor and the feed conductor are thereby electrically bonded together by an integral metal/metal bond, and
d) applying separate insulation material to the contact points.

13. The method according to claim 12, wherein the contact points are formed in succession with a thermal welding tool.

14. The method according to claim 13, wherein the thermal welding tool is heated in pulses for making the contact points, with
a first heat pulse burning and/or removing the insulation of the associated feed conductor and the insulation of the feed conductor at least partially, and
a second heat pulse bonding the respective function conductor and the feed conductor to each other.

15. The method according to claim 13, wherein the welding tool has a tip with a surface between 0.1 mm² and 8 mm² .

16. The method according to claim 12, wherein the separate insulation material is applied as a liquid at the contact points formed and is cured by activation.

17. The method according to claim 12, wherein the functional conductors extend outside the textile substrate at the contact points, the first feed conductor being arranged between the functional conductors and the textile substrate, and a protective strip is temporarily interposed between the first feed conductor and the textile substrate for making the contact points.

18. Use of a functional textile according to claim 1 for heating, in particular interior spaces of a motor vehicle.

19. The use according to claim 18, wherein a decorative layer is provided on the textile substrate, and the functional conductors are arranged on a side of the textile substrate covered by the decorative layer.
